(19) United States
(12) Patent Application Publication
(10) Pub. No.: US 2009/0303422 A1
(43) Pub. Date: Dec. 10, 2009

(54) DISPLAY SUBSTRATE, METHOD OF MANUFACTURING THE SAME AND DISPLAY PANEL HAVING THE SAME

(76) Inventors: Gwan-Soo Kim, Seoul (KR); Byoung-Joo Kim, Gyeonggi-do (KR); Sang-Hun Lee, Gyeonggi-do (KR); Min Kang, Seoul (KR); Sun-Young Chang, Gyeonggi-do (KR)

Correspondence Address: Haynes and Boone, LLP;IP Section, 2323 Victory Avenue, SUITE 700, Dallas, TX, 75219, US

(21) Appl. No.: 12/414,327

(22) Filed: Mar. 30, 2009

(30) Foreign Application Priority Data
Jun. 9, 2008 (KR) 2008-53569

(51) Int. Cl. G02F 1/1335; G03F 7/20; G02F 1/1333

(52) U.S. Cl. 349/106; 430/312; 349/110

(57) ABSTRACT

Embodiments of the present disclosure provide a display substrate, a method of manufacturing the same and a display panel having the same. In an embodiment, a switching element is formed near a crossing area of a gate line and a data line to connect with the gate and data lines. A color filter layer includes a light-blocking partition pattern defining a light-transmitting area and a color filter disposed on the light-transmitting area. A light-blocking partition pattern includes an insulation pattern which covers the switching element, the gate line and the data line along a normal line direction of a base substrate and a light-blocking layer pattern formed from substantially the same pattern as an insulation layer pattern on an upper surface of the insulation layer pattern. A pixel electrode layer is disposed on the color filter to be connected to the switching element. An alignment margin between an upper substrate and a lower substrate may be removed, so that the aperture ratio of a pixel of the display panel may be increased.

### PRIORITY STATEMENT

This application claims priority under 35 U.S.C. §119 to Korean Patent Application No. 2008-53569, filed on Jun. 9, 2008 in the Korean Intellectual Property Office (KIPO), the contents of which are herein incorporated by reference in their entirety.

### BACKGROUND

1. Technical Field

Example embodiments of the present invention generally relate to a display substrate, a method of manufacturing the display substrate, and a display panel having the display substrate. More particularly, example embodiments of the present invention relate to a display substrate capable of enhancing operational reliability and manufacturing yield, a method of manufacturing the display substrate, and a display panel having the display substrate.

2. Description of the Related Art

Generally, a liquid crystal display (LCD) device includes an LCD panel and a light source module providing the LCD panel with light. The LCD panel includes a liquid crystal layer controlling light transmittance. When the arrangement of liquid crystal molecules of the liquid crystal layer is altered, the light transmittance of the liquid crystal layer is changed to display desired information on the LCD panel.

In order to control liquid crystal molecules of the liquid crystal layer, the LCD panel includes a pixel electrode and a common electrode that is opposite to the pixel electrode by interposing the liquid quid crystal layer therebetween. In each pixel electrode, a switching element is connected to the pixel electrode, and a gate line and a data line are electrically connected to the switching element, respectively. Conventionally, a lower substrate is called an array substrate, which has the pixel electrode and the switching element arranged thereon.

The LCD panel includes color filters and a black matrix dividing the color filters to block light in order to display color. The color filters and the black matrix may be disposed on an upper substrate.

When a pixel electrode array and a color filter array are disposed on the lower substrate and the upper substrate, respectively, an alignment margin between the array substrate and the color filter substrate may decrease the aperture ratio of a pixel during a manufacturing process of the array substrate and the color filter substrate.

Thus, a color filter on array (COA) structure and a black matrix on array (BOA) structure have been developed. In the COA structure, a color filter is formed on the array substrate. In the BOA structure, a color filter and a black matrix are formed on the array substrate.

According to the COA structure or the BOA structure, an alignment margin with the upper substrate is not considered, so that the aperture ratio of a pixel may be increased. Moreover, the structure of the upper substrate is simple, so that manufacturing costs may be reduced.

However, even though an organic material of a nonmetal is employed in the black matrix, the black matrix and a switching element, or the black matrix and a data line may form parasitic capacitance in the BOA structure. Due to the parasitic capacitance, display defects such as crosstalk may be generated on a display screen.

Moreover, developing characteristics of a black matrix material is low, so that after a developing process the black matrix material remains in a light-transmitting area. Thus, display defects may be generated on the LCD panel, and the aperture ratio of the LCD panel may be decreased. Moreover, electric short defects and coupling defects may be generated in the LCD panel.

Furthermore, due to characteristics of the black matrix material, it is difficult to form the black matrix having a thickness of no less than about 1.5 μm. As a color filter has a thickness of about 3 μm, a step difference between the black matrix and the color filter may be large. As a result, the step coverage of a layer covering the black matrix and the color filter may be poor, and thus the manufacturing yield of the display substrate is reduced.

### SUMMARY

Example embodiments of the present invention provide a display device capable of enhancing operational reliability and manufacturing yield by changing the structure of a light-blocking pattern.

Example embodiments of the present invention also provide a method of manufacturing the above-mentioned display substrate.

Example embodiments of the present invention further provide a display panel having the above-mentioned display substrate.

According to one aspect of the present invention, a display substrate includes a base substrate, a signal line, a switching element, a color filter layer, and a pixel electrode. The signal line includes a gate line disposed on the base substrate and a data line crossing the gate line. The switching element is formed near a crossing area of the gate line and the data line to connect with the gate line and the data line. The color filter layer includes a light-blocking partition pattern defining a light-transmitting area and a color filter disposed on the light-transmitting area. The light-blocking partition pattern includes an insulation pattern which covers the switching element and the signal line along a normal line direction of the base substrate and a light-blocking layer pattern formed from substantially the same pattern as the insulation layer pattern on an upper surface of the insulation layer pattern. The pixel electrode layer is disposed on the color filter to connect an output electrode of the switching element.

In an example embodiment of the present invention, the display substrate may further include a protective layer covering the base substrate having the switching element and the signal line formed thereon. The color filter layer is formed on the protective layer. Thus, the light-blocking partition pattern is formed as a black matrix on array (BOA) type. The pixel electrode layer is formed on the color filter. The pixel electrode layer is connected to an output electrode of the switching element through a contact hole formed through the color filter and the protective layer.

In an example embodiment of the present invention, the insulation layer pattern may include a positive photoresist material. The light-blocking pattern may include a negative photoresist material.

In an example embodiment of the present invention, the thickness of the color filter may be about 2.7 μm to about 3.3 μm, and the thicknesses of the insulation pattern and the light-blocking layer pattern may be about 1.3 μm to about 1.6 μm, respectively.

In an example embodiment of the present invention, the insulation layer pattern may have hydrophilic properties with respect to the color filter. The light-blocking layer pattern may have hydrophobic properties with respect to the color filter. The switching element and the signal line may be formed on the light-blocking layer pattern, and the pixel electrode layer may be formed on a protective layer covering the switching element and the signal line. That is, the color filter layer may be formed as an array on color filter (AOC) type.

In an example embodiment of the present invention, the display substrate may further include a planarization layer and a light-blocking pattern. The planarization layer may cover a whole surface of the base substrate having the color filter and the light-blocking partition pattern formed thereon. The light-blocking pattern may be formed on the switching element and the signal line that are formed on the planarization layer.

According to another one aspect of the present invention, there is provided a method of manufacturing a display substrate. In the method, a signal line is formed on a base substrate and a switching element connected to the signal line. A light-blocking partition pattern is formed, which includes an insulation pattern which covers the switching element and the signal line and a light-blocking layer pattern formed from substantially the same pattern as the insulation layer pattern on an upper surface of the insulation layer pattern. A color filter is formed on a light-transmitting area between signal lines defining the light-blocking partition pattern. A pixel electrode layer is formed on the color filter to connect with an output electrode of the switching element.

In an example embodiment of the present invention, in order to form the light-blocking partition pattern, a protective layer is formed, which covers a base substrate having the switching element and the signal line formed thereon. An insulation layer including a positive photoresist is formed on the protective layer. A light-blocking layer including a negative photoresist is formed on the insulation layer. The insulation layer and the light-blocking layer are patterned to form the insulation layer pattern and a light-blocking layer pattern on the insulation layer pattern. In order to form the insulation layer pattern and the light-blocking layer pattern, the light-blocking layer pattern is formed by removing the light-blocking layer through a photo-etching process. The insulation layer is exposed by using the light-blocking layer pattern as a mask. The exposed insulation layer is developed to remove the exposed insulation layer and the remaining light-blocking layer formed on the exposed insulation layer to form the insulation layer pattern.

In an example embodiment of the present invention, the insulation layer may be formed by using hydrophilic properties with respect to the color filter, and the light-blocking layer may be formed by using hydrophobic properties with respect to the color filter. The color filter may be formed by printing a color ink on the light-transmitting area.

According to still another embodiment of the present invention, there is provided a method of manufacturing a display substrate. In the method, a light-blocking partition pattern is formed, which includes an insulation layer pattern on a base substrate and a light-blocking layer pattern formed from substantially the same pattern as the insulation layer pattern on an upper surface of the insulation layer pattern. A color filter is formed on a light-transmitting area defining the light-blocking partition pattern. A signal line is formed on a base substrate and a switching element connected to the signal line. A protective layer is formed, which covers a base substrate having the switching element and the signal line formed thereon. A pixel electrode layer is formed on the protective layer in correspondence with the color filter. The pixel electrode layer is connected to an output electrode of the switching element.

In an example embodiment of the present invention, in order to form the light-blocking partition pattern, an insulation layer including a positive photoresist may be formed on the base substrate. A light-blocking layer including a negative photoresist may be formed on the insulation layer. The insulation layer and the light-blocking layer may be patterned to form the light-blocking layer pattern on an upper surface of the insulation layer pattern. In order to form the insulation layer and the light-blocking layer pattern, the light-blocking layer pattern may be formed through an exposing process of the light-blocking layer and developing process of the exposed light-blocking layer. The insulation layer may be exposed by using the light-blocking layer pattern as a mask. The exposed insulation layer may be developed to remove the exposed insulation layer and the remaining light-blocking layer formed on the exposed insulation layer to form the insulation layer pattern.

In an example embodiment of the present invention, the insulation layer may be formed by using hydrophilic properties with respect to the color filter, and the light-blocking layer may be formed by using hydrophobic properties with respect to the color filter.

In an example embodiment of the present invention, a planarization layer may be further formed, which covers the color filter and the light-blocking partition pattern to have a planarizing surface which the signal line and the switching element will be formed. Moreover, a light-blocking pattern may be further formed on the switching element and the signal line.

According to further still another embodiment of the present invention, a display panel includes a first substrate including an upper substrate and a common electrode formed on the upper substrate, a second substrate and a liquid crystal layer interposed between the first and second substrates. The second substrate includes a lower substrate, a plurality of signal lines, a switching element and a color filter layer. The signal lines include a gate line formed on the upper substrate and a data line crossing the gate line. The switching element is connected to the signal line. The color filter layer includes a light-blocking partition pattern and a color filter. The light-blocking partition pattern includes an insulation layer pattern covering the switching element and the signal line and a light-blocking layer pattern formed from substantially the same pattern as the insulation layer pattern on an upper surface of the insulation layer pattern. The color filter is formed on the light-transmitting area. The light-blocking partition pattern defines a light-transmitting area between the signal lines.

In an example embodiment of the present invention, the second substrate may further include a protective layer covering the lower substrate having the switching element and the signal line formed thereon. The color filer layer may be formed on an upper surface of the protective layer. The pixel electrode layer may be formed on an upper surface of the color filter.

In an example embodiment of the present invention, the insulation layer pattern may include a positive photoresist, and the light-blocking layer pattern may include a negative photoresist. The insulation layer may be formed by using hydrophilic properties with respect to the color filter, and the light-blocking layer may be formed by using hydrophobic properties with respect to the color filter.

In an example embodiment of the present invention, the switching element and the signal line may be formed on the light-blocking layer pattern, and the pixel electrode layer may be formed on a protective layer covering the switching element and the signal line in correspondence with the color filter.

According to one or more embodiments of a display substrate, a method of manufacturing the display substrate and a display panel having the display substrate, a switching element controlling a pixel electrode layer and a color filter layer are formed on the same substrate. Thus, an alignment margin between an upper substrate and a lower substrate may be removed, so that the aperture ratio of a pixel of the display panel may be increased.

Moreover, a light-blocking partition pattern including a color filter layer may have a double layer of an insulation layer pattern and a light-blocking pattern. Thus, a formation of parasitic capacitance between a channel portion of a switching element and a light-blocking layer pattern, and between a data line and the light-blocking layer pattern may be prevented, so that the operational reliability of the display panel may be enhanced.

Moreover, a remaining light-blocking layer may be removed from a light-transmitting area, and a step difference between the color filter and the light-blocking layer pattern may be decreased, so that coating defects of an alignment layer may be decreased to enhance the manufacturing yield of the display substrate.

### BRIEF DESCRIPTION OF THE DRAWINGS

The above and other features and advantages of the embodiments of the present disclosure will become more apparent by describing in detailed example embodiments thereof with reference to the accompanying drawings.

FIG. 1 is a plan view illustrating a display substrate according to Embodiment 1 of the present invention;

FIG. 2 is a cross-sectional view taken along a line I-I′ of FIG. 1;

FIG. 3 is a cross-sectional view of a display panel having the display substrate of FIG. 2;

FIGS. 4A to 4G are cross-sectional views illustrating a method of manufacturing the display substrate of FIG. 2 according to one or more embodiments;

FIG. 5 is a plan view illustrating a display substrate according to Embodiment 2 of the present invention;

FIG. 6 is a cross-sectional view taken along a line II-II′ of FIG. 5;

FIG. 7 is a cross-sectional view of a display panel having the display substrate of FIG. 6; and

FIGS. 8A to 8F are cross-sectional views illustrating a method of manufacturing the display substrate of FIG. 6 according to one or more embodiments.

### DETAILED DESCRIPTION

Embodiments of the present invention are described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present disclosure to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present invention will be explained in detail with reference to the accompanying drawings.

### Example Embodiment 1

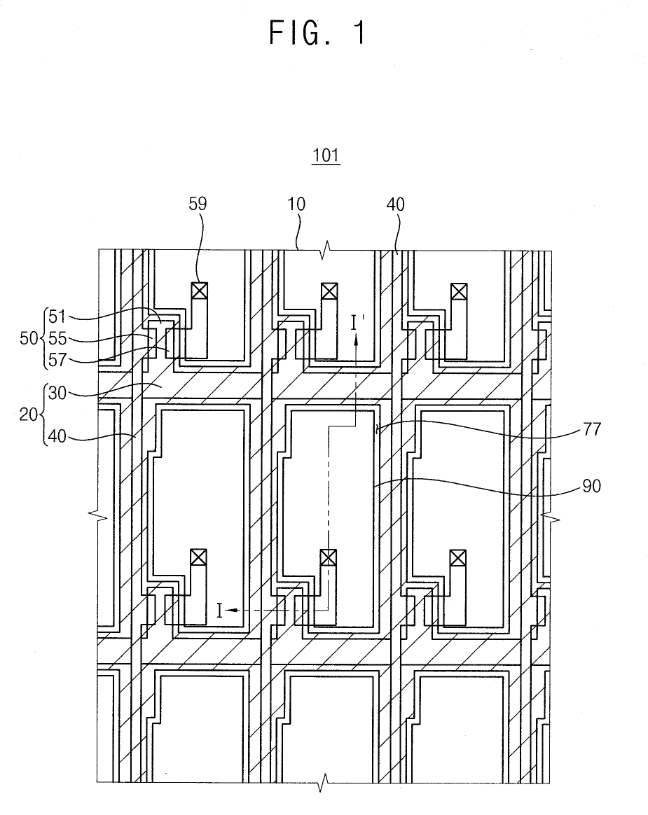

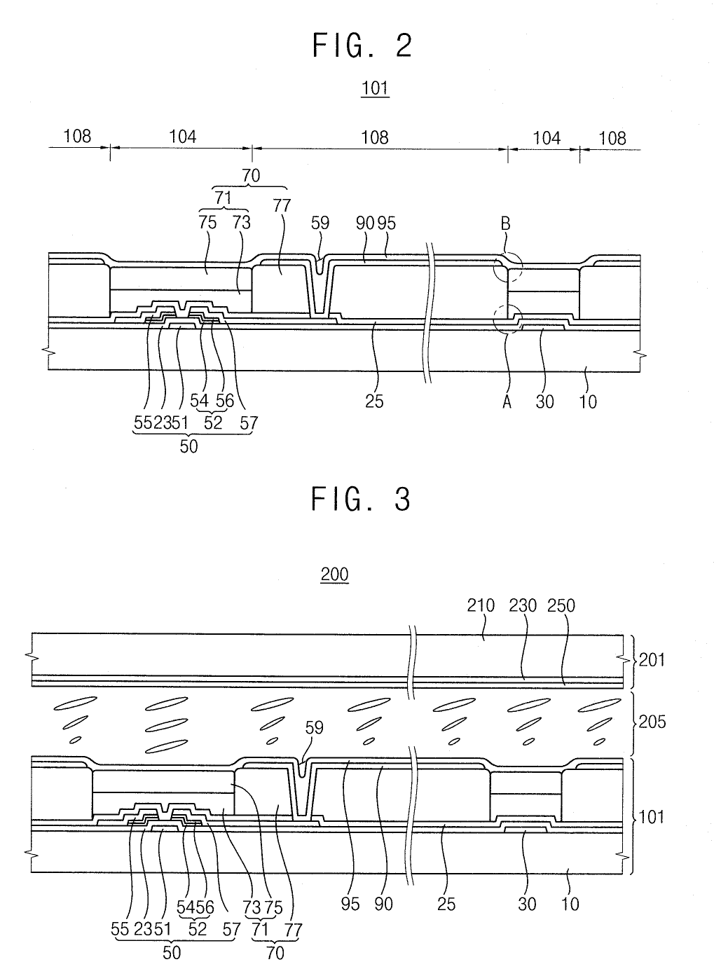

FIG. 1 is a plan view illustrating a display substrate according to Embodiment 1 of the present invention. FIG. 2 is a cross-sectional view taken along a line I-I′ of FIG. 1.

Referring to FIGS. 1 and 2, a display substrate 101 includes a base substrate 10, a signal line 20, a switching element 50, a protective layer 25, a color filter layer 70 and a pixel electrode layer 90.

The display substrate 101 according to the present embodiment may be formed as a color filter on array (COA) type. Moreover, the display substrate 101 according to the present embodiment may be formed as a black matrix on array (BOA) type.

The base substrate 10 may include a transparent glass substrate.

The signal line 20 includes a plurality of gate lines 30 and a plurality of data lines 40. The gate lines 30 may be formed on the base substrate 10 at uniform intervals. The gate lines 30 may include aluminum (Al), molybdenum (Mo), titanium (Ti), chromium (Cr), copper (Cu), an alloy of the above metals, etc. The display substrate 101 may further include a gate insulation layer 23 which covers the gate lines 30 to insulate the gate lines 30. The gate insulation layer 23 may include an inorganic insulation layer including an inorganic material such as silicon nitride (SiNx) or silicon oxide (SiOx).

The data lines 40 may be formed on the gate insulation layer 23 at uniform intervals. The data lines 40 may include aluminum (Al), molybdenum (Mo), titanium (Ti), chromium (Cr), copper (Cu), an alloy of the above metals, etc.

The switching element 50 is formed in a crossing area between a gate line 30 and a data line 40. The switching element 50 is electrically connected to the gate line 30 and the data line 40, respectively. The switching element 50 may include a gate electrode 51, a gate insulation layer 23, a semiconductor layer 52, a source electrode 55 and a drain electrode 57.

The gate electrode 51 is extended from the gate line 30. The semiconductor layer 52 is formed on the gate insulation layer 23 in correspondence with the gate electrode 51. The semiconductor layer 52 includes an amorphous silicon (a-Si) layer 54, and an ohmic contact layer 56 formed on the amorphous silicon layer 54. In this embodiment, the ohmic contact layer 56 includes n+ amorphous silicon (n+ a-Si). For example, n+ impurities are implanted into the amorphous silicon (a-Si) layer 54 at a high concentration to form the ohmic contact layer 56. The source electrode is extended from the data line 40 to be formed on the semiconductor layer 52. A portion of the source electrode is overlapped with the gate electrode 51 when viewed on a plan view. The drain electrode 57 is disposed on the semiconductor layer 52 opposite to the source electrode 55 with respect to the gate electrode 51. A portion of the drain electrode 57 is overlapped with the gate electrode 51. The semiconductor layer 52 between the source electrode 55 and the drain electrode 57 may form a channel portion.

The gate electrode 51 receives a gate signal that is a control signal through the gate line 30. The source electrode receives a data signal that is an image signal through the data line 40. When the gate signal is applied to the gate electrode 51, the data signal may be outputted to the drain electrode 57 through the channel portion.

The protective layer 25 covers the base substrate 10 having the switching element 50 formed thereon. Thus, the protective layer 25 covers the switching element 50 and the data line 40. The protective layer 25 may include a high-resistance organic insulation material such as an acryl-series organic compound, a polyimide, etc. Moreover, the protective layer 25 may include an inorganic material such as silicon nitride (SiNx) or silicon oxide (SiOx).

The color filter layer 70 includes a light-blocking partition pattern 71 and a color filter 77. The light-blocking partition pattern 71 is disposed in correspondence with the switching element 50, the gate line 30 and the data line 40. In this embodiment, the light-blocking partition pattern 71 is formed on the protective layer 25. The light-blocking partition pattern 71 blocks external light that is incident into the switching element 50, the gate line 30 and the data line 40. The light-blocking partition pattern 71 forms a space in which color filters 77 are to be disposed.

An area in which light is blocked by the light-blocking partition pattern 71 is defined as a light-blocking area 104. An area which is not covered by the light-blocking partition pattern 71 is defined as a light-transmitting area 108. The light-blocking partition pattern 71 includes an insulation layer pattern 73 and a light-blocking layer pattern 75.

The insulation layer pattern 73 is disposed on the protective layer 25 and the light-blocking area 104. That is, the insulation layer pattern 73 covers the switching element 50, the gate line 30 and the data line 40 in a normal line direction toward an upper surface of the base substrate 10. A portion of the drain electrode 57 which corresponds to the semiconductor layer 52 is covered by the insulation layer pattern 73, and the remaining drain electrode 57 is disposed at a peripheral of the insulation layer pattern 73. Thus, the insulation layer pattern 73 has a matrix shape.

The insulation layer pattern 73 may include an organic insulation material including a color photoresist. Electric insulation properties of the insulation layer pattern 73 are strong, and the insulation layer pattern 73 has a dielectric constant of about 4 or less, so that the insulation layer pattern 73 does not form a storage capacitor. Thus, the insulation layer pattern 73 is formed between the light-blocking layer pattern 75 and the channel portion and between the light-blocking layer pattern 75 and the data line 40 to restrain a formation of parasitic capacitance. Accordingly, the operational reliability of the switching element 50 and the display substrate 101 may be enhanced.

The insulation layer pattern 73 may include a positive photoresist in order to decrease the number of manufacturing processes. Moreover, the insulation layer pattern 73 may have hydrophilic properties with respect to the color filter 77 in order to enhance contact characteristics with the color filter 77. For example, the insulation layer pattern 73 may be formed with a thickness of about 1.5 μm to about 2.0 μm.

The light-blocking layer pattern 75 is formed on the insulation layer pattern 73 in a substantially identical pattern as the insulation layer pattern 73. The light-blocking layer pattern 75 blocks external light that is incident into the switching element 50, the gate line 30 and the data line 40.

The light-blocking layer pattern 75 may include an organic material in order to decrease parasitic capacitance between the switching element 50 and the data line 40. Thus, the light-blocking layer pattern 75 may include a photosensitivity organic material in which carbon black, for example, a black pigment such as insulation carbon, is dispersed into acrylic resin.

The light-blocking layer pattern 75 may include a negative photoresist in order to decrease the number of manufacturing processes of the display substrate 101. When the light-blocking layer pattern 75 includes the negative photoresist, the thickness of the color filter 77 may be about 2.7 μm to about 3.3 μm, and the thicknesses of the insulation pattern layer 73 and the light-blocking layer pattern 75 may be about 1.3 μm to about 1.6 μm, respectively.

When the light-blocking layer pattern 75 has hydrophilic properties with respect to the color filter 77, an edge of the color filter 77 may be easily extended toward an upper surface of the light-blocking layer pattern 75 such that defects of a connection with an adjacent color filter 77 may be generated. Thus, the light-blocking layer pattern 75 may have hydrophobic properties with respect to the color filter 77 in order to enhance the shape of the color filter 77.

The color filter 77 may include a color filter photoresist. The color filter 77 may include a red color filter portion, a green color filter portion and a blue color filter portion. The red, green and blue color filter portions are formed on a plurality of light-transmitting areas 108 defined by the light-blocking partition pattern 71.

As described above, the color filter 77 may have hydrophilic properties in comparison with the insulation layer pattern 73, and may have hydrophobic properties in comparison with the light-blocking layer pattern 75. The hydrophilic properties denote properties which allow easy combination with water molecules. Conventionally, when a predetermined material has a polarity, the material has hydrophilic properties, and when a predetermined material does not have a polarity, the material has hydrophobic properties. An example of a material with hydrophilic properties is a material having a hydroxyl group (—OH). Most pigments for forming the color filter 77 are materials having hydrophilic properties.

As the color filter 77 has hydrophilic properties with respect to the insulation layer pattern 73, the color filter 77 and the insulation layer pattern 73 are compatible with each other in a lower area ‘A’ where the color filter 77 meets the insulation layer 73 so that the color filter 77 may fully fill a space defined by the insulation layer pattern 73.

The color filter 77 and the light-blocking layer pattern 75 are incompatible with each other in an upper area ‘B’ where the color filter 77 meets the light-blocking layer pattern 75, so that the color filter 77 is not overlapped with the light-blocking layer pattern 75 and an edge of the color filter 77 has a gentle curved shape. Thus, a step difference between the color filter 77 and the light-blocking layer pattern 75 may be decreased.

The color filter 77 may have a thickness of about 3 μm. Thus, when the light-blocking layer pattern 75 only forms a partition, in order to decrease a step difference, the thickness of the light-blocking layer pattern 75 may be about 3 μm. However, due to material properties of the light-blocking layer pattern 75, it may be impossible to form the thickness of about 3 μm.

That is, when the light-blocking layer pattern 75 includes a carbon to form the thickness of no less than about 3 μm, developing properties of the light-blocking layer pattern 75 is decreased. In addition, the light-blocking layer pattern 75 may not have a sufficient hardness, so that it may be impossible to form a fine pattern.

However, in the present embodiment, the insulation layer pattern 73 is formed below the light-blocking layer pattern 75. Thus, the insulation layer pattern 73 and the light-blocking layer pattern 75 form a partition. When the thickness of the insulation layer pattern 73 is about 1.5 μm and the thickness of the light-blocking layer pattern 75 is about 1.5 μm, even though the thickness of the light-blocking layer pattern 75 is about 1.5 μm, a step difference with the color filter 77 may be decreased.

A contact hole exposing a portion of the drain electrode 57 is formed through the protective layer 25 and the color filter 77 in correspondence with the drain electrode 57.

The pixel electrode layer 90 is formed on the color filter 77, and is extended toward the contact hole to be connected to the drain electrode 57. The pixel electrode layer 90 may include indium tin oxide (ITO), indium zinc oxide (IZO), amorphous-indium tin oxide (a-ITO), etc.

As the insulation layer pattern 73 restrains a formation of parasitic capacitance, the pixel electrode layer 90 may overlap with a portion of the gate line 30 and a portion of the data line 40 so that the aperture ratio of a pixel may be enhanced.

The display substrate 101 may further include an alignment layer 95. The alignment layer 95 may include a polyimide.

As described above, display substrate 101 according to the present embodiment has a step difference between the light-blocking layer pattern 75 and the color filter 77 that is small, and an edge of the color filter 77 has a gentle slope to be connected to the light-blocking layer pattern 75. Thus, the alignment layer 95 is prevented from being open between the color filter 77 and the light-blocking layer pattern 75.

FIG. 3 is a cross-sectional view of a display panel having the display substrate 101 of FIG. 2. Referring to FIG. 3, a display panel 200 includes a first substrate 201, a second substrate 101 and a liquid crystal layer 205.

The first substrate 201 includes an upper substrate 210, a common electrode 230 and an upper alignment layer 250.

The upper substrate 210 may include a transparent glass substrate. The common electrode layer 230 is formed on the upper substrate 210. The common electrode layer 230 may include a material the same as that of the pixel electrode layer 90 as illustrated in FIG. 2. The common electrode layer 230 may receive a uniform common voltage.

The upper alignment layer 250 is formed on the common electrode layer 230. The upper alignment layer 250 may include a material the same as that of the alignment layer 95 as illustrated in FIG. 2.

The second substrate 101 includes a lower substrate 10, a signal line 20, a switching element 50, a protective layer 25, a color filter layer 70 and a pixel electrode 90. The second substrate 101 may be substantially the same as the display substrate 101 according to the embodiments of FIGS. 1 and 2. Thus, identical reference numerals are used in FIG. 3 to refer to components that are the same or like those shown in FIGS. 1 and 2, and thus, a detailed description thereof will be omitted.

The liquid crystal layer 205 is disposed between the first substrate 201 and the second substrate 101.

When a data signal, that is, a data voltage is applied to the pixel electrode layer 90, an electric field is altered between the pixel electrode layer 90 and the common electrode layer 230. Thus, an arranging direction of liquid crystal molecules is altered between the pixel electrode layer 90 and the common electrode layer 230. Therefore, a light transmittance through the liquid crystal layer 205 is controlled, so that an image is displayed.

In the display panel 200 according to the present embodiment, the color filter layer 70 is not formed on the first substrate 201. The second substrate 101 includes the switching element 50, the pixel electrode layer 90 and the color filter layer 70.

When the first substrate 201 and the second substrate 101 are combined with each other, it is not necessary to give an alignment margin between the first substrate 201 and the second substrate 101. Therefore, a ratio of the size of the light-transmitting area 108, that is, the aperture ratio, may be increased. Moreover, assembly of the first substrate 201 and the second substrate 101 may be easier.

Moreover, the insulation layer pattern 73 is disposed between the light-blocking layer pattern 75 and the channel portion of the switching element 50, and is also disposed between the light-blocking layer pattern 75 and the data line 40, so that a formation of parasitic capacitance may be prevented.

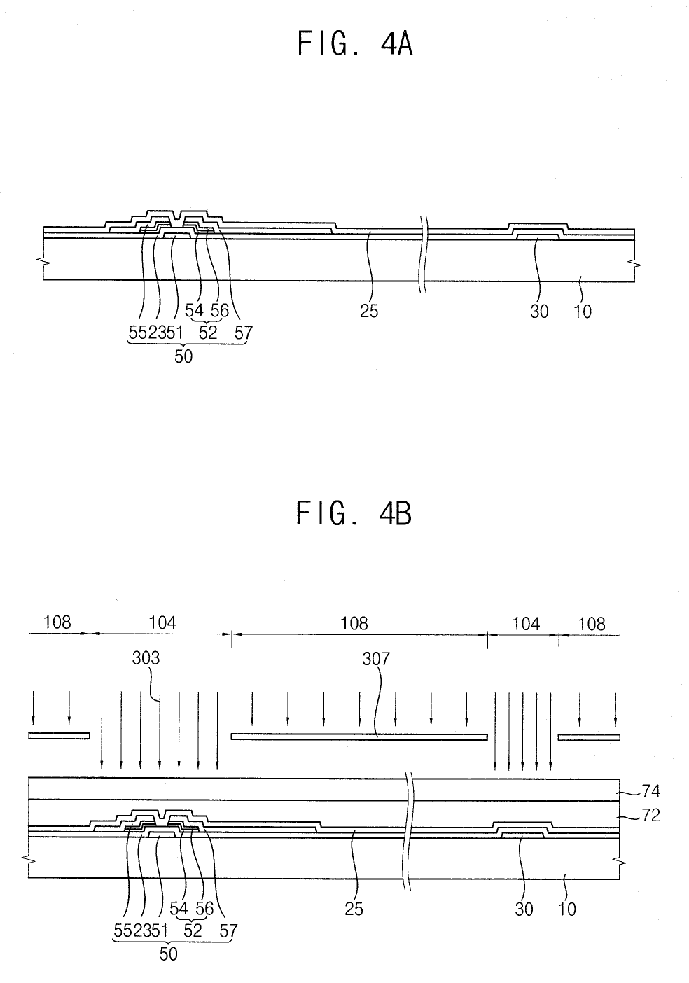

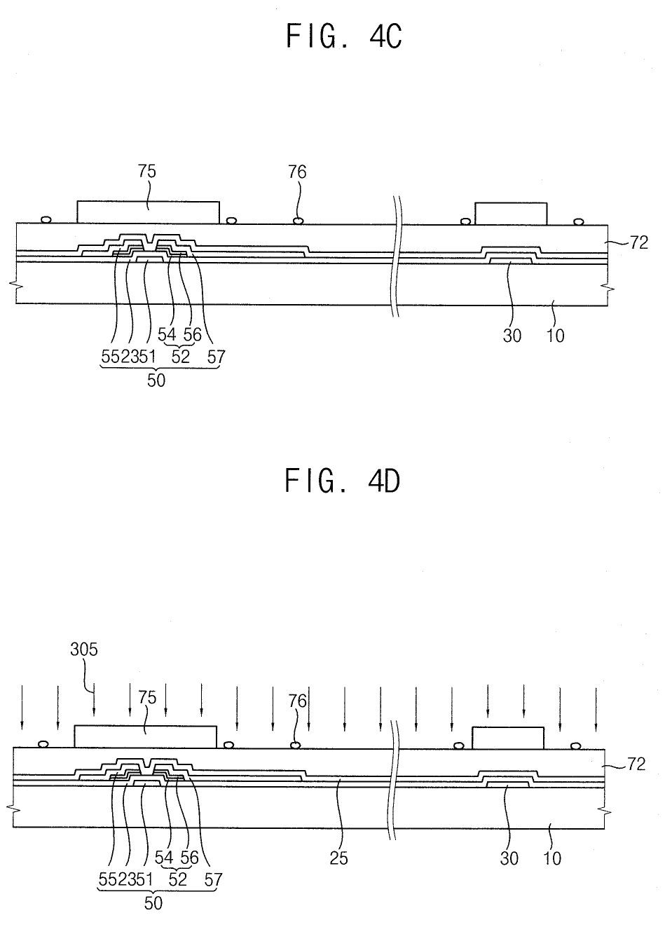

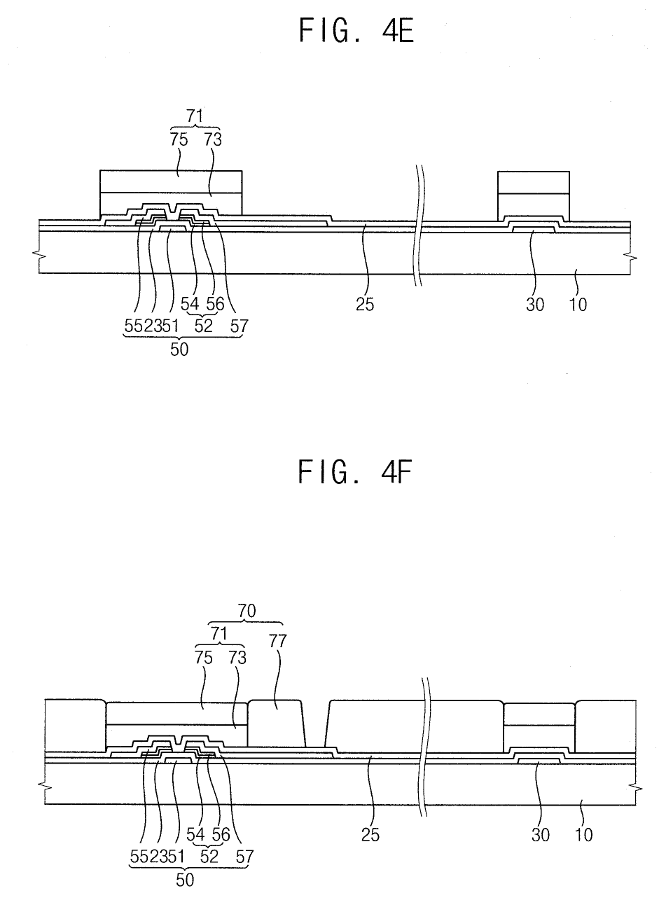

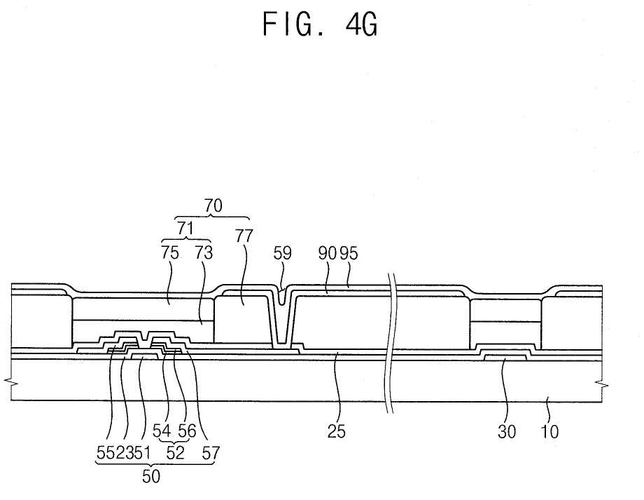

FIGS. 4A to 4G are cross-sectional views illustrating a method of manufacturing the display substrate of FIG. 2 according to one or more embodiments. A method of manufacturing a display substrate will be described with references used in the description of the display substrate 101 as shown in the embodiment of FIG. 2.

Referring to FIG. 4A, in order to manufacture a display substrate, the signal line 20, the switching element 50 connected to the signal line 20 and the protective layer 25 covering the base substrate 10 having the signal line 20 and the switching element 50 formed thereon are formed on the base substrate 10. The structure of the switching element 50 is substantially the same as that of the switching element 50 of the embodiment of FIG. 2, and a method of manufacturing the signal line 20, the switching element 50 and the protective layer 25 is well known in the art. Thus, a detailed description thereof will be omitted.

As shown in FIGS. 4B to 4E, the light-blocking partition pattern 71 is formed according to one or more embodiments. In a method of manufacturing the display substrate according to the present embodiment, the light-blocking partition pattern 71 is formed on the protective layer 25.

As shown in FIG. 4B, an organic insulation material including a positive photoresist such as acryl-series organic composition, a polyimide, etc., is spread on the protective layer 25 to form an insulation layer 72. The positive photoresist may have hydrophilic properties with respect to the color filter 77. The insulation layer 72 may be formed to have a thickness of about 1.5 μm.

The light-blocking layer 74 including a negative-type color photoresist is formed on the insulation layer 72 through a spin coating method or a slit-and-spin coating method. A negative-type color photoresist may include a photosensitivity organic material in which carbon black, for example, a black pigment such as insulation carbon, is dispersed into acrylic resin.

The photosensitivity organic material may have hydrophobic properties with respect to the color filter 77. The light-blocking layer 74 may be formed to have a thickness of about 1.5 μm.

Then, the light-blocking layer 74 and the insulation layer 72 are patterned. For example, the light-blocking layer 74 may be exposed by ultraviolet (UV) rays, as shown in FIG. 4B, through an optical mask 307 having an opening corresponding to the light-blocking area 104 formed therethrough. The light-blocking layer 74 corresponding to the light-blocking area 104 is exposed, and the remaining light-blocking layer 74 is not exposed.

The light-blocking layer 74 includes a negative photoresist. Thus, as shown in FIG. 4C, the light-blocking layer pattern 75 corresponding to the light-blocking area 104 is formed, and the light-blocking layer 74 corresponding to the remaining area is developed to be removed. Here, remaining substances 76 of the light-blocking layer 74 may remain on the insulation layer 72 in correspondence with the light-transmitting area 108 defined on the base substrate 10.

Alternatively, when the light-blocking layer 74 is directly formed on the protective layer 25 without a formation of the insulation layer 72, the remaining substance of the light-blocking layer 74 remains on the protective layer 25 corresponding to the light-transmitting area 108 after patterning the light-blocking layer 74. Thus, it may be impossible to fully remove the remaining substance 76 of the light-blocking layer 74 remaining on the protective layer 25.

In the method of manufacturing a display device according to the present embodiment, the remaining substance 76 of the light-blocking layer 74 remains in correspondence with the light-transmitting area 108 which will be removed in the following process. Thus, when the insulation layer 72 is removed, the remaining substance 76 of the light-blocking layer 74 may be removed from the base substrate 10 without an additional process.

As shown in FIG. 4D, the insulation layer 72 is exposed through the light-blocking layer pattern 75 as a mask. The insulation layer 72 includes a positive photoresist. Thus, when the exposed insulation layer 72 is developed using a developing solution such as tetramethyl ammonium hydroxide (TMAH), as shown in FIG. 4E, the insulation layer 72 corresponding to the light-transmitting area 108 is removed, and the insulation layer pattern 73 is formed between the light-blocking layer pattern 75 and the protective layer 25. Thus, the light-blocking partition pattern 71 is formed in correspondence with the light-blocking area 104.

Then, as shown in FIG. 4F, the color filter 77 is formed in a color space defined by the light-blocking partition pattern 71 and the protective layer 25 in correspondence with the light-transmitting area 108.

Red, green and blue color inks may be printed in a plurality of color spaces through an inkjet method, and then the color inks may be cured through, for example, a heat curing process or a UV curing process to form the color filter 77.

As described above, the color ink has hydrophilic properties with respect to the insulation layer pattern 73. Thus, the color filter 77 and the insulation layer pattern 73 are in contact with each other, so that an interval gap may not be generated between the color filter 77 and the insulation layer pattern 73. Also, the color ink is incompatible with the light-blocking layer pattern 75 formed on the insulation layer pattern 73, so that the color ink does not flow to an upper surface of the light-blocking layer pattern 75. Thus, an upper surface of the color filter 77 is protruded toward an upper direction of the color filter 77, and an edge of the color filter 77 having a gentle slope is connected to a corner portion of an upper surface of the light-blocking layer pattern 75.

Alternatively, a negative color photoresist, in which a red pigment is dispersed into an acrylic resin, is spread on a base substrate having the light-blocking partition pattern 71 formed thereon to form a color photoresist layer, and then a photo-etching process, a heat curing process, or a UV curing process may be performed on the color photoresist layer to form a red color filter. In addition, the green and blue color filters may be formed on the light-transmitting areas 108 through an identical process.

The contact hole 59 may be formed after the color ink is cured. Alternatively, when the color filter 77 is formed by patterning the color photoresist layer, the contact hole 59 may be patterned. Here, the contact hole 59 opens the color filter 77 in correspondence with a portion of the drain electrode 57. That is, a portion except for the protective layer 25 corresponding to the contact hole 59 may not be open.

As shown in FIG. 4G, the protective layer 25 corresponding to the contact hole 59 is open, and then an optically transparent and electrically conductive material such as indium tin oxide (ITO), tin oxide (ITO), indium zinc oxide (IZO), amorphous indium tin oxide (a-ITO), etc., is deposited on the base substrate 10 having the color filter 77 and the light-blocking partition pattern 71 formed thereon. The optically transparent and electrically conductive material is patterned through a photo-etching process to form the pixel electrode layer 90 on the color filter 77. The pixel electrode layer 90 is electrically connected to the drain electrode 57 through the contact hole 59.

The alignment layer 95 including a polyimide is formed on the base substrate 10 having the pixel electrode 90 formed thereon to complete the display substrate 101. The alignment layer 95 is formed on the pixel electrode layer 90 to be substantially planarized.

In this embodiment, due to the insulation layer pattern 73, a height of an upper surface of the light-blocking layer pattern 73 may be substantially the same as that of an upper surface of the color filter 77 with respect to the protective layer 25. Thus, a step difference between the light-blocking layer pattern 75 and the color filter 77 is decreased, so that an edge of the color filter 77 may have a gentle slope surface. Therefore, the alignment layer 95 may not be opened between the light-blocking layer pattern 75 and the color filter 77 so that it is easily formed thereon.

### Example Embodiment 2

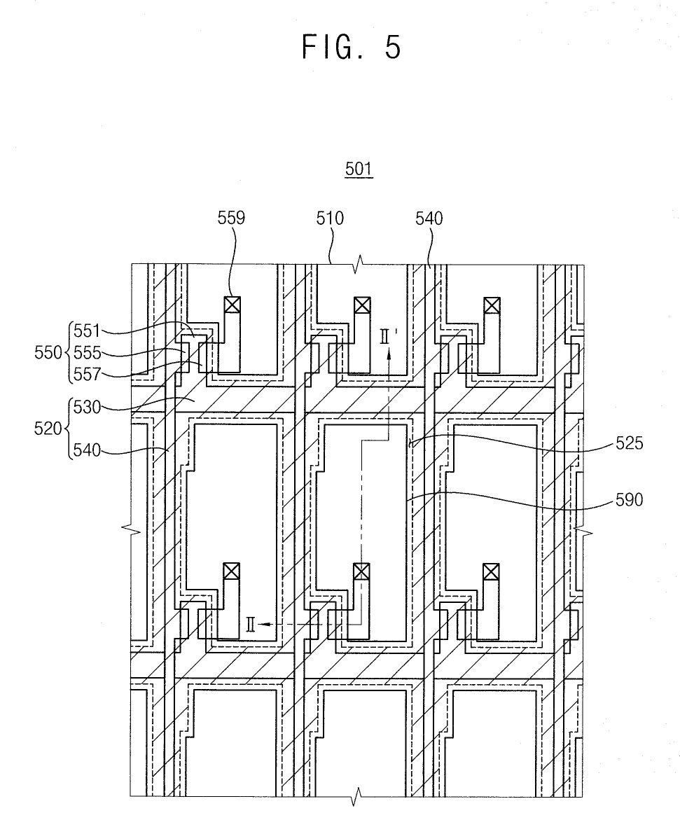

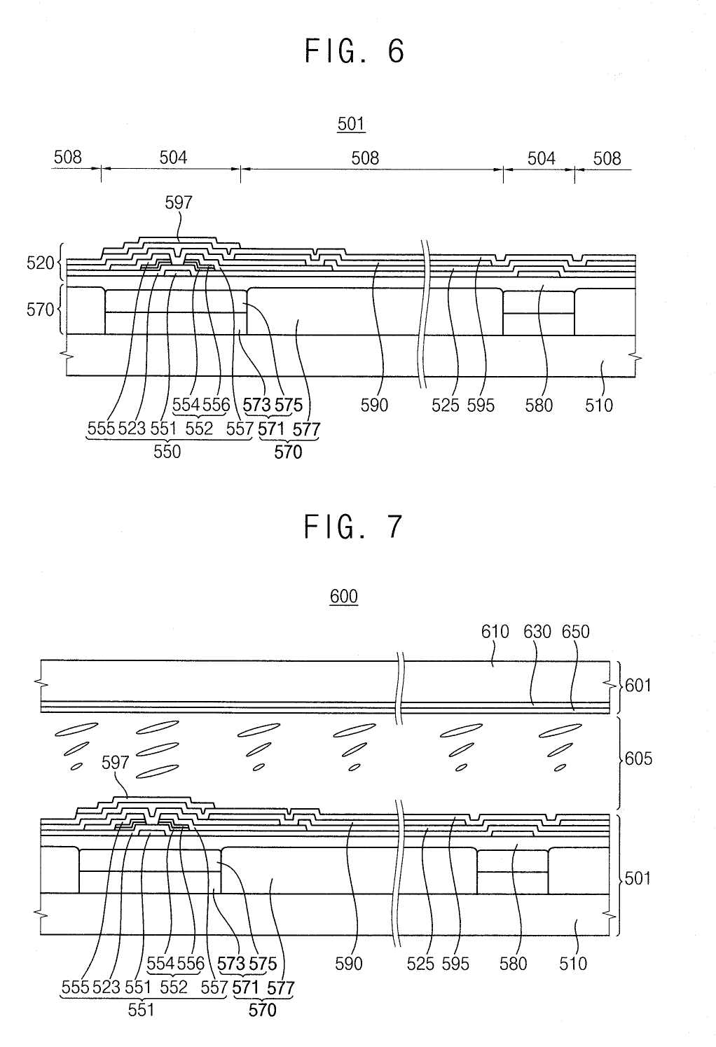

FIG. 5 is a plan view illustrating a display substrate 501 according to Embodiment 2 of the present invention. FIG. 6 is a cross-sectional view taken along a line II-II′ of FIG. 5.

Referring to FIGS. 5 and 6, a display substrate 501 includes a base substrate 510, a signal line 520, a switching element 550, a protective layer 525, a color filter layer 570 and a pixel electrode layer 590.

In the present embodiment, the color filter layer 570 is formed between the base substrate 510 and the switching element 550. That is, the display substrate 501 according to the present embodiment is formed as an array on color filter (AOC) type.

The color filter layer 570 is formed on the base substrate 510. The color filter layer 570 includes a light-blocking partition pattern 571 and a color filter 577.

An insulation layer pattern 573 is formed on a light-blocking area 504 defined on an upper surface of the base substrate 510, and a light-blocking layer pattern 575 is formed on the insulation layer pattern 573 as the same pattern. The color filter 577 is formed in a light-transmitting area 508 defined by the light-blocking partition pattern 571.

The color filter layer 570 may further include a planarization layer 580. The planarization layer 580 is formed on the base substrate 510 having the light-blocking partition pattern 571 and the color filter 577 formed thereon.

The signal line 520, the switching element 550 and the protective layer 525 are substantially the same as the signal line 20, the switching element 50 and the protective layer 25, respectively, as shown in the embodiments of FIGS. 1 and 2, except for at least that the signal line 520, the switching element 550 and the protective layer 525 are formed on the planarization layer 580. Thus, similar reference numerals are used in FIGS. 5 and 6 to refer to components that are the same or like those shown in the embodiments of FIGS. 1 and 2, and thus, a detailed description thereof will be omitted.

The display substrate 501 may include an alignment layer 595 and a light-blocking pattern 597. The alignment layer 595 covers a base substrate 510 having the protective layer 525 formed thereon. The light-blocking pattern 587 is formed on the alignment layer 595 in correspondence with the switching element 550 and the signal line 520, so that it is intercept for light incident to the switching element 550 and the signal line 520. The light-blocking pattern 597 may include a material substantially identical to the light-blocking layer pattern 575. Alternatively, the thickness of the light-blocking pattern 597 formed on the switching element 550 may be higher, so that a portion of the light-blocking pattern 597 may perform a function of a spacer.

FIG. 7 is a cross-sectional view of a display panel having the display substrate 501 of FIG. 6. Referring to FIG, 7, a display panel 600 includes a first substrate 601, a second substrate 501 and a liquid crystal layer 605.

The display panel 600 is substantially the same as the display panel 200 of the embodiments of FIG. 3, except for at least that the second substrate 501 is substantially the same as the display substrate 501 of FIGS. 5 and 6. Thus, identical reference numerals are used in FIG. 7 to refer to components that are the same or like those shown in FIG. 3, and thus, a detailed description thereof will be omitted.

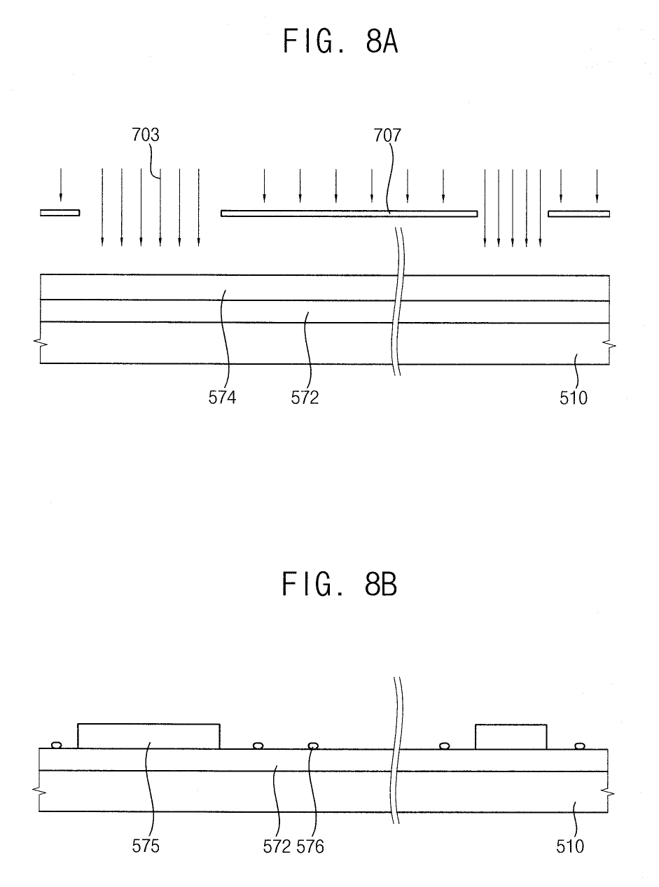

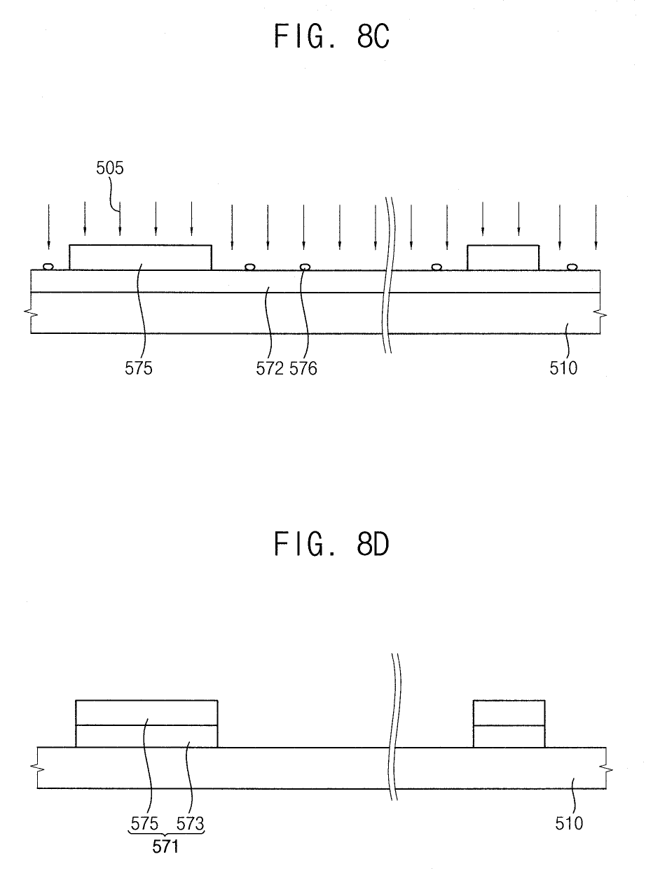

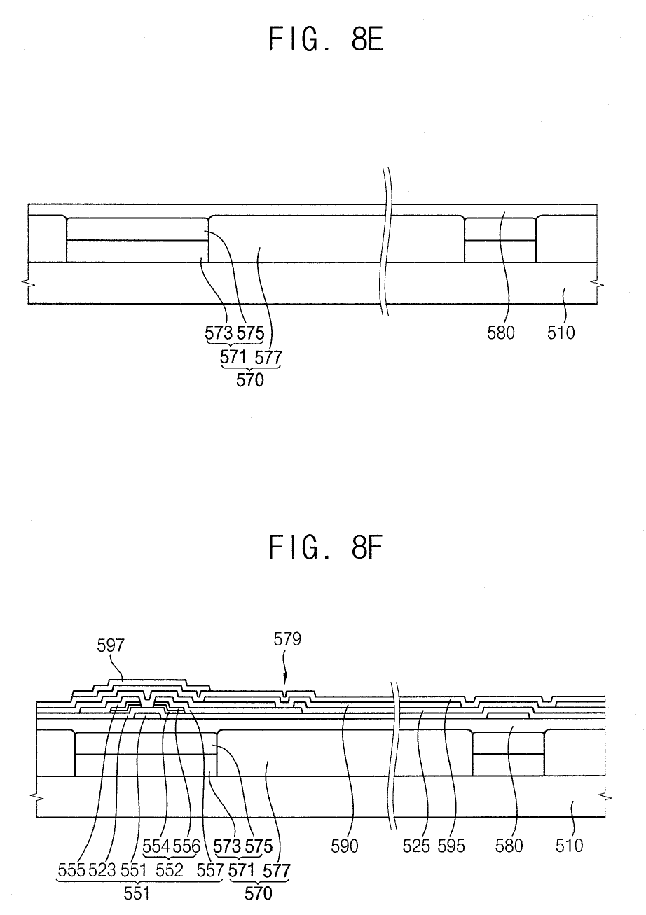

FIGS. 8A to 8F are cross-sectional views illustrating a method of manufacturing the display substrate of FIG. 6 according to one or more embodiments.

A method of manufacturing a display substrate according to the present embodiment is substantially the same as the method of manufacturing the display substrate of the embodiments of FIGS. 4A to 4G, except for at least that the color filter layer 570 is formed on the base substrate 510 before the signal line 520, the switching element 550 and the protective layer 525. Thus, identical reference numerals are used in FIGS. 8A to 8F to refer to components that are the same or like those shown in the embodiments of FIGS. 4A to 4G, and thus, a detailed description thereof will be omitted.

Referring to FIGS. 8A to 8D, the light-blocking partition pattern 571 and the color filter 577 are formed on the base substrate 510. For example, an insulation layer 572 and a light-blocking layer 574 are formed on the base substrate 510 as shown in FIG. 8A, and then the insulation layer 572 and the light-blocking layer 574 are exposed through an optical mask.

Then, the light-blocking layer 574 is developed to form the light-blocking layer pattern 575 in correspondence with the light-blocking area 504 as shown in FIG. 8B.

As shown in FIG. 8C, the insulation layer 572 is exposed by using the light-blocking layer pattern 575 as a mask. The exposed insulation layer 572 is developed to remove the exposed insulation layer 572, and the light-blocking layer 576 remains disposed on the exposed insulation layer 572 to form the light-blocking layer pattern 575 on the insulation layer pattern 573 as shown in FIG. 8D. Thus, the light-blocking partition pattern 571 is formed.

As shown in FIG. 8E, the color filter 577 is formed in the light-transmitting area 508 defined by the light-blocking partition pattern 571, and the planarization layer 580 is formed on the base substrate 510 having the light-blocking partition pattern 571 and the color filter 577 formed thereon.

As shown in FIG. 8F, the signal line 520, the switching element 550 and the protective layer 525 are formed on the planarization layer 580.

A contact hole 579 exposing a portion of the drain electrode 557 is formed through the protective layer 525. The pixel electrode layer 590 is formed on the protective layer 525 in correspondence with the color filter 577. The pixel electrode layer 590 is connected to the drain electrode 557 through the contact hole 579.

An alignment layer 595 is formed on the base substrate 510 having the protective layer 525 formed thereon, and a light-blocking pattern 597 is formed on the alignment layer 595 in correspondence with the switching element 550 and the signal line 520 to complete a display substrate 501. The light-blocking pattern 597 may include a material the same as that of the light-blocking layer pattern 575.

According to a display substrate, a method of manufacturing the display substrate and a display panel having the display substrate, an alignment margin may be removed between an upper substrate and a lower substrate, thereby increasing the aperture ratio of a pixel of the display panel. Moreover, a formation of parasitic capacitance between a switching element and a light-blocking layer pattern, and between a data line and a light-blocking layer pattern may be prevented, so that the operational reliability of the display substrate and the display panel may be enhanced. Furthermore, a remaining light-blocking layer may be removed from a light-transmitting area, and a step difference between the color filter and the light-blocking layer pattern may be decreased, so that coating defects of an alignment layer are decreased to enhance the manufacturing yield of the display substrate.

Therefore, embodiments of the present invention may be applied to application fields enhancing the operational reliability of a display substrate and a display panel having a color filter on array (COA) type, a black matrix on array (BOA) type, an array on color filter (AOC) type, etc., and the manufacturing yield thereof.

The foregoing is illustrative of the present disclosure and is not to be construed as limiting thereof. Although a few example embodiments of the present invention have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present disclosure is defined by the following claims, with equivalents of the claims to be included therein.

What is claimed is:

1. A display substrate comprising:
a base substrate;
a signal line comprising a gate line disposed on the base substrate and a data line crossing the gate line;
a switching element formed near a crossing area of the gate line and the data line to connect with the gate line and the data line;
a color filter layer comprising a light-blocking partition pattern defining a light-transmitting area and a color filter disposed on the light-transmitting area, the light-blocking partition pattern comprising an insulation pattern which covers the switching element and the signal line along a normal line direction of the base substrate and a light-blocking layer pattern formed from substantially the same pattern as the insulation layer pattern on an upper surface of the insulation layer pattern; and
a pixel electrode layer disposed on the color filter to connect an output electrode of the switching element.

2. The display substrate of claim 1, further comprising a protective layer covering the base substrate having the switching element and the signal line formed thereon, wherein the color filter layer is formed on the protective layer.

3. The display substrate of claim 2, wherein the insulation layer pattern comprises a positive photoresist material.

4. The display substrate of claim 3, wherein the light-blocking pattern comprises a negative photoresist material.

5. The display substrate of claim 4, wherein the thickness of the color filter is about 2.7 μm to about 3.3 μm, and the thicknesses of the insulation pattern and the light-blocking layer pattern are about 1.3 μm to about 1.6 μm, respectively.

6. The display substrate of claim 4, wherein the insulation layer pattern has hydrophilic properties with respect to the color filter.

7. The display substrate of claim 6, wherein the light-blocking layer pattern has hydrophobic properties with respect to the color filter.

8. The display substrate of claim 1, wherein the switching element and the signal line are formed on the light-blocking layer pattern, and the pixel electrode layer is formed on a protective layer covering the switching element and the signal line.

9. The display substrate of claim 8, further comprising:
a planarization layer covering a whole surface of the base substrate having the color filter and the light-blocking partition pattern formed thereon; and
a light-blocking pattern formed on the switching element and the signal line that are formed on the planarization layer.

10. A method of manufacturing a display substrate, the method comprising:
forming a signal line formed on a base substrate and a switching element connected to the signal line;
forming a light-blocking partition pattern comprising an insulation pattern which covers the switching element and the signal line and a light-blocking layer pattern formed from substantially the same pattern as the insulation layer pattern on an upper surface of the insulation layer pattern;
forming a color filter on a light-transmitting area between signal lines defining the light-blocking partition pattern; and
forming a pixel electrode layer formed on the color filter to connect with an output electrode of the switching element.

11. The method of claim 10, wherein forming the light-blocking partition pattern comprises:
forming a protective layer covering a base substrate having the switching element and the signal line formed thereon;
forming an insulation layer comprising a positive photoresist on the protective layer;
forming a light-blocking layer comprising a negative photoresist on the insulation layer; and
patterning the insulation layer and the light-blocking layer to form the insulation layer pattern and a light-blocking layer pattern on the insulation layer pattern.

12. The method of claim 11, wherein forming the insulation layer pattern and the light-blocking layer pattern comprises:
forming the light-blocking layer pattern by removing the light-blocking layer through a photo-etching process;
exposing the insulation layer by using the light-blocking layer pattern as a mask; and
developing the exposed insulation layer to remove the exposed insulation layer and the remaining light-blocking layer formed on the exposed insulation layer to form the insulation layer pattern.

13. The method of claim 12, wherein the insulation layer is formed by using hydrophilic properties with respect to the color filter, and the light-blocking layer is formed by using hydrophobic properties with respect to the color filter.

14. The method of claim 13, wherein the color filter is formed by printing a color ink on the light-transmitting area.

15. A method of manufacturing a display substrate, the method comprising:
forming a light-blocking partition pattern comprising an insulation layer pattern on a base substrate and a light-blocking layer pattern formed from substantially the same pattern as the insulation layer pattern on an upper surface of the insulation layer pattern;
forming a color filter on a light-transmitting area defining the light-blocking partition pattern;
forming a signal line on a base substrate and a switching element connected to the signal line;
forming a protective layer covering a base substrate having the switching element and the signal line formed thereon; and
forming a pixel electrode layer on the protective layer in correspondence with the color filter, the pixel electrode layer being connected to an output electrode of the switching element.

16. The method of claim 15, wherein forming the light-blocking partition pattern comprises:
forming an insulation layer comprising a positive photoresist on the base substrate;
forming a light-blocking layer comprising a negative photoresist on the insulation layer; and
patterning the insulation layer and the light-blocking layer to form the light-blocking layer pattern on an upper surface of the insulation layer pattern.

17. The method of claim 16, wherein forming the insulation layer and the light-blocking layer pattern comprises:
forming the light-blocking layer pattern through an exposing process of the light-blocking layer and developing process of the exposed light-blocking layer;
exposing the insulation layer by using the light-blocking layer pattern as a mask; and
developing the exposed insulation layer to remove the exposed insulation layer and the remaining light-blocking layer formed on the exposed insulation layer to form the insulation layer pattern.

18. The method of claim 17, wherein the insulation layer is formed by using hydrophilic properties with respect to the color filter, and the light-blocking layer is formed by using hydrophobic properties with respect to the color filter.

19. The method of claim 15, further comprising:
forming a planarization layer covering the color filter and the light-blocking partition pattern to have a planarizing surface on which the signal line and the switching element will be formed; and
forming a light-blocking pattern on the switching element and the signal line.

20. A display panel comprising:
a first substrate comprising an upper substrate and a common electrode formed on the upper substrate;
a second substrate comprising:
a lower substrate;
a plurality of signal lines comprising a gate line formed on the upper substrate and a data line crossing the gate line;
a switching element connected to the signal line; and
a color filter layer comprising:
a light-blocking partition pattern comprising an insulation layer pattern covering the switching element and the signal line and a light-blocking layer pattern formed from substantially the same pattern as the insulation layer pattern on an upper surface of the insulation layer pattern; and
a color filter formed on the light-transmitting area, the light-blocking partition pattern defining a light-transmitting area between the signal lines; and
a liquid crystal layer interposed between the first and second substrates.

21. The display panel of claim 20, wherein the second substrate further comprises a protective layer covering the lower substrate having the switching element and the signal line formed thereon,
the color filter layer is formed on an upper surface of the protective layer, and
the pixel electrode layer is formed on an upper surface of the color filter.

22. The display panel of claim 21, wherein the insulation layer pattern comprises a positive photoresist, and the light-blocking layer pattern comprises a negative photoresist.

23. The display panel of claim 22, wherein the insulation layer is formed by using hydrophilic properties with respect to the color filter, and the light-blocking layer is formed by using hydrophobic properties with respect to the color filter.

24. The display panel of claim 20, wherein the switching element and the signal line are formed on the light-blocking layer pattern, and the pixel electrode layer is formed on a protective layer covering the switching element and the signal line in correspondence with the color filter.
